(19) United States
(12) Patent Application Publication
(10) Pub. No.: US 2010/0252805 A1
(43) Pub. Date: Oct. 7, 2010

(54) GaN Nanorod Arrays Formed by Ion Beam Implantation

(75) Inventors: Wei-Kan Chu, Pearland, TX (US); Hye-Won Seo, Houston, TX (US); Quark Y. Chen, Houston, TX (US); Li-Wei Tu, Houston, TX (US); Ching-Lien Hsaio, Houston, TX (US); Xuemei Wang, Houston, TX (US); Yen-Jie Tu, Houston, TX (US)

Correspondence Address: AKIN GUMP STRAUSS HAUER & FELD LLP, 1111 Louisiana Street, 44th Floor, Houston, TX, 77002, US

(73) Assignee: UNIVERSITY OF HOUSTON, Houston, TX (US)

(21) Appl. No.: 11/993,677

(22) PCT Filed: Jun. 29, 2006
(86) PCT No.: PCT/US06/25609

§ 371 Date: Jun. 22, 2010

Related U.S. Application Data
(60) Provisional application No. 60/696,020, filed on Jun. 29, 2005.

(51) Int. Cl. H01L 29/66; H01L 21/20

(52) U.S. Cl. 257/11; 438/506; 257/9; 257/E21.09; 257/E29.168; 977/762

(57) ABSTRACT

A method of preparing nanorod arrays using ion beam implantation is described that includes defining a pattern on a substrate and then implanting ions into the substrate using ion beam implantation. Next, a thin film is deposited on the substrate. During film growth, nanotrenches form and catalyze the formation of nanorods through capillary condensation. The resulting nanorods are aligned with the supporting matrix and are free from lattice and thermal strain effect. The density, size, and aspect ratios of the nanorods can be varied by changing the ion beam implantation and thin film growth conditions resulting in control of emission efficiency.

This application claims the benefit under 35 U.S.C. §119(e) of U.S. Provisional Patent Application No. 60/696,020, filed on Jun. 29, 2005, which is incorporated by reference in its entirety herein for all purposes.

The U.S. Government has a paid-up license in this invention, and the right, in limited circumstances, to require the patent owner to license others on reasonable terms as provided for by the terms of the Department of Energy Grant No. DE-FG02-05ER46208 and the National Science Foundation (NSF) Grant No. DMR-0404542.

The present invention relates to the general field of formation of nanorod arrays using ion beam implantation.

Current methods for producing nanorod array patterns use a metallic catalyst to catalyze growth using a Vapor-Liquid-Solid process. A thin layer of catalytic metal heated above the eutectic temperature is deposited on the substrate in the presence of a vapor-phase source of the substrate. Adsorption of the vapor phase on the metal catalyst creates a eutectic liquid phase that consumes the catalyst. Further adsorption of the substrate into the liquid phase causes supersaturation resulting in nanorod growth. Droplets form on top of the growing nanorods to drive further Vapor-Liquid-Solid (VLS) growth. Problems inherent in the process include: 1) the catalyst itself creates undesirable impurities in the nanorods, which degrade the physical properties, 2) the structure usually has no supporting matrix materials, causing mechanical instability, 3) the nanorods usually have a pedestal-shaped bottom making them susceptible to strain effect causing structural defects, and 4) the nanostructures can be unaligned and randomly distributed causing varying electric fields, which create emission inefficiency in field emission devices. Furthermore, the tangled structure of typical nanowires causes uncontrollable and undesirable changes in the scale, which alters the local fields. The bending may result in outright electrical shorting between the nanowires.

E-beam lithography and thy-etch also can be used to fabricate capillary tubes for nanorod growth. However, size restrictions apply, limiting the diameter of the capillary tube in e-beam lithography and limiting the depth-to-diameter aspect ratio in dry-etch. Additionally, the e-beam lithography technique employs a scanning method resulting in an inherently slow and costly process unsuitable for industrial applications.

The present invention provides a method of growing straightly aligned single crystal nanorods in designed patterned arrays that includes, in one aspect of the invention providing a substrate, defining a pattern on the substrate, implanting ions into the substrate using ion beam implantation, and depositing thin films on the substrate.

In a second aspect, the invention provides a method of growing straightly aligned single crystal GaN nanorods in designed patterned arrays that includes providing a Si substrate, defining a pattern on the substrate using lithography, implanting ions into the substrate using ion beam implantation, wherein the step of implanting ions into the substrate comprises providing ions selected from the group consisting of Si, N, SiN, Ga, GaN, and combinations thereof, and depositing GaN thin films on the substrate via molecular beam epitaxy growth, wherein nanotrenches form to catalyze the growth of GaN nanorods through capillary condensation of Ga atoms.

In a third aspect, the invention provides a method of growing straightly aligned single crystal GaN nanorods in designed patterned arrays that includes providing a Si substrate, defining a pattern on the substrate using photolithography, implanting Si ions into the substrate using ion beam implantation, wherein density and size of nanorods in the array pattern is controlled by the dosage, energy, and temperature of the ion implantation process, and depositing GaN thin films on the substrate via nitrogen plasma enhanced molecular beam epitaxy growth, wherein nanotrenches form to catalyze the growth of GaN nanorods through capillary condensation of Ga atoms, wherein the GaN nanorod arrays are aligned relative to a surface of the substrate, wherein a length-to-diameter aspect ratio of the GaN nanorods is controlled by growth time, temperature, and Ga/N ratio.

In a fourth aspect, an emitter device prepared by a process of doping the straightly aligned single crystal nanorods with dopants where the nanorods are produced by providing a substrate, defining a pattern on the substrate, implanting ions into the substrate using ion beam implantation, and depositing thin films on the substrate.

In a fifth aspect, straightly aligned single crystal nanorods in designed patterned arrays produced by providing a substrate, defining a pattern on the substrate, implanting ions into the substrate using ion beam implantation, and depositing thin films on the substrate.

FIG. 1 illustrates the lithography and implantation of ions onto the substrate in accordance with one embodiment of the invention;

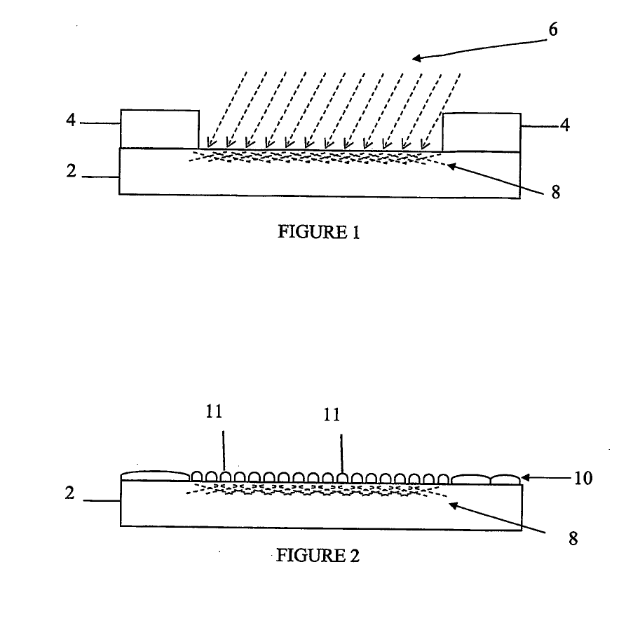

FIG. 2 illustrates the island impingements formed during initial thin film growth after ion implantation in accordance with one embodiment of the invention;

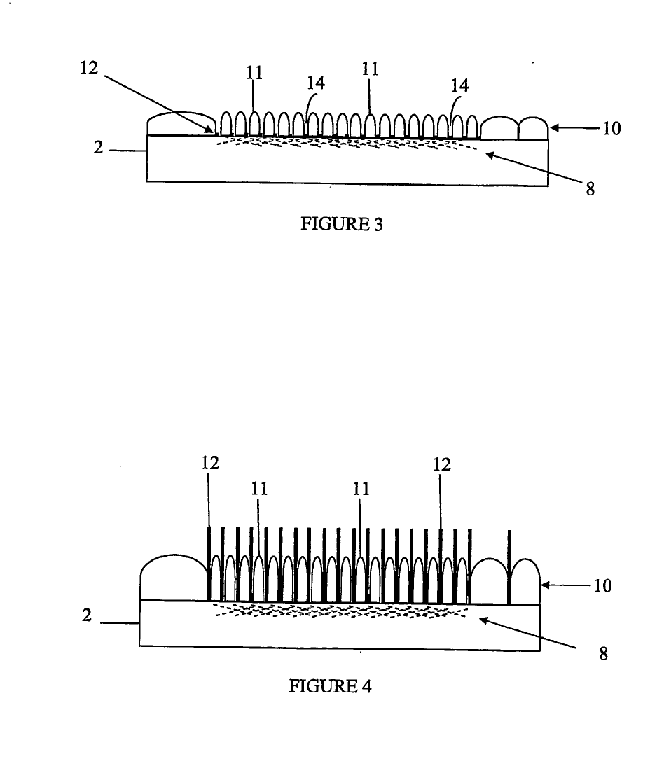

FIG. 3 illustrates the nanorod foundations during the second phase of film growth in accordance with one embodiment of the invention; and

FIG. 4 illustrates the nanorods during the third phase of film growth in accordance with one embodiment of the invention.

The present invention proposes a method for growing straightly aligned single crystal nanorods in designed pattern arrays, by using ion beam assisted array patterns to grow nanorods using capillary condensation.

According to one embodiment of the present invention, straightly aligned single crystal nanorods in designed patterned arrays are grown by providing a substrate 2, using lithography 4 to define a pattern on the substrate, implanting ions 8 into the substrate 2 using ion beams 6, and depositing thin films 10 on the substrate 2 to form nanotrenches 14 and catalyze the growth of nanorods 12 through capillary condensation.

Referring to FIG. 1, lithography 4 is used to define a pattern on the substrate 2. The substrate 2 can be any material composed of any elements or compounds such as those of group IV elements on the periodic table including, but not limited to, Si, Ge, and Si₁₋ₓGeₓ alloys, as well as group III-V and II-VI compounds and alloys including but not limited to ZnO, GaP, InN, AlN, Al₁₋ₓInₓN, Ga₁₋ₓInₓN, Ga₁₋ₓAlₓN, and GaAs. The lowercase x represents any value from zero to one. Additionally, various types of lithography can be used to define a pattern on the substrate including, but not limited to, photolithography, stencile masking, imprinting by pressing, e-beam lithography, and x-ray lithography.

After lithography, ions 8 are implanted in the substrate using ion beams 6. The ions 8 induce defects in the substrate, which later provide nucleation sites to foster nanorod growth during thin film growth. Any ions 8 that induce defects in the substrate can be used including, but not limited to, Si, N, SiN, Ga, or GaN implanted individually or in combination. The pattern for the nanorod array can be further defined by the placement of the ions 8. Additionally, the variables of the ion implantation process, including the amount of keV energy, temperature, dosage, and ion species can be altered to control the density and size of the nanorods in the array pattern.

In a specific embodiment of the invention, ion selection is a function of the composition of the thin films 10 and the composition of the substrate 2. Examples of ions 8 used for each thin film composition and substrate composition are shown below in Table I. The lower case x represents any value from zero to one. The letters X, Y, and Z represent the first, second, and third elements of the substrate respectively. For example, in the substrate Al₂O₃, X=Al, Y=O, and Z is not present. In another example, in the substrate SrTiO₃, X=Sr, Y=Ti, and Z=O. The letters B and C represent any elements.

TABLE I
Sample ion choices for each substrate and thin film combination.

| Thin Film | Substrate | Ion Choices |
|---|---|---|
| GaN | XYZ | Ga, N, GaN, XN, GaY, XY, XZ, YZ, XYZ, X, Y, Z |
| ZnO | XYZ | Zn, O, ZnO, ZnY, XO, XY, XZ, YZ, XYZ, X, Y, Z |
| GaAs | XYZ | Ga, As, GaAs, GaY, XAs, XY, XZ, YZ, XYZ, X, Y, Z |
| SiGe | XYZ | Si, Ge, SiGe, SiY, XGe, XY, XZ, YZ, XYZ, X, Y, Z |
| InN | XYZ | In, N, InN, InY, XN, XY, XZ, YZ, XYZ, X, Y, Z |
| GaP | XYZ | Ga, P, GaP, XP, GaY, XY, XZ, YZ, XYZ, X, Y, Z |
| AlN | XYZ | Al, N, AlN, XN, AlY, XY, XZ, YZ, XYZ, X, Y, Z |
| Al₁₋ₓInₓN | XYZ | Al, N, In, AlN, InN, XN, AlY, InY, Al₁₋ₓInₓN, XY, |
| | | XZ, YZ, XYZ, X, Y, Z |
| Ga₁₋ₓInₓN | XYZ | Ga, N, In, GaN, InN, XN, GaY, InY, Ga₁₋ₓInₓN, XY, |
| | | XZ, YZ, XYZ, X, Y, Z |
| Ga₁₋ₓAlₓN | XYZ | Ga, N, Al, GaN, AlN, XN, GaY, AlY, Ga₁₋ₓAlₓN, XY, |
| | | XZ, YZ, XYZ, X, Y, Z |
| InBC | XYZ | In, B, InX, InY, InZ, InXY, InXZ, InYZ, InXYZ, BX, |
| | | BY, BZ, BXY, BXZ, BYZ, BXYZ, InBX, InBY, |
| | | InBZ, InBXY, InBXZ, InBYZ, InBXYZ, InBCX, |
| | | InBCY, InBCZ, InBCXY, InBCXZ, InBCYZ, |
| | | InBCXYZ |
| ZnBC | XYZ | Zn, B, ZnX, ZnY, ZnZ, ZnXY, ZnXZ, ZnYZ, |
| | | ZnXYZ, BX, BY, BZ, BXY, BXZ, BYZ, BXYZ, |
| | | ZnBX, ZnBY, ZnBZ, ZnBXY, ZnBXZ, ZnBYZ, |
| | | ZnBXYZ, ZnBCX, ZnBCY, ZnBCZ, ZnBCXY, |
| | | ZnBCXZ, ZnBCYZ, ZnBCXYZ |
| GaBC | XYZ | Ga, B, GaX, GaY, GaZ, GaXY, GaXZ, GaYZ, |
| | | GaXYZ, BX, BY, BZ, BXY, BXZ, BYZ, BXYZ, |
| | | GaBX, GaBY, GaBZ, GaBXY, GaBXZ, GaBYZ, |
| | | GaBXYZ, GaBCX, GaBCY, GaBCZ, GaBCXY, |
| | | GaBCXZ, GaBCYZ, GaBCXYZ |

Referring to FIG. 2, in a specific embodiment of the invention, a thin film 10 of GaN is deposited on the substrate. The implanted ions provide increased nucleation sites causing islands 11 of GaN to form. By altering the molecular beam epitaxy variables of time, temperature, and Ga/N ratio during thin film growth, the length-to-diameter aspect ratio of the nanorods can be controlled within a range of ˜10 to ˜300.

Embodiments consistent with the present disclosure use thin film growth methods of molecular beam epitaxy, chemical vapor deposition, physical vapor deposition, pulsed laser deposition, and sputtering. Regardless of the film growth method used, the variables of time, temperature, and gas mixture ratio can be altered to control the length-to-diameter aspect ratio of the nanorods.

Referring to FIG. 3, in a specific embodiment of the invention, as the islands 11 grow, nanotrenches 14 are formed. Referring to FIG. 4, capillary condensation of Ga atoms occurs in the nanotrenches 14 and catalyzes nanorod 12 growth. Once formed, nanorods 12 continue to grow by Vapor-Liquid-Solid growth.

Other embodiments consistent with the present disclosure use thin films of ZnO, GaAs, SiGe, InN, GaP, AlN, Al₁₋ₓInₓN, Ga₁₋ₓInₓN, Ga₁₋ₓAlₓN, Ga alloys, Zn alloys, and In alloys instead of GaN. The lowercase x represents any value from zero to one. The thin film used is determined by the desired nanorods. For example, to produce ZnO nanorods, a thin film of ZnO would be used, and the Zn/O ratio could be controlled during film growth to control the length-to-diameter aspect ratio of the nanorods. In a specific embodiment using ZnO thin film, referring to FIG. 4, capillary condensation of Zn atoms occurs in the nanotrenches 14 and catalyzes nanorod 12 growth.

The resulting nanorod arrays can be used in all semiconductor materials including group IV elements such as Si, Ge, and Si₁₋ₓGeₓ alloys, group III-V compounds and alloys such as GaAs, and group II-VI compounds and alloys such as ZnO. The lowercase x represents any value from zero to one. The direct band gap of the nanorods can be engineered by alloying with In and Al to obtain materials of a wide range of band gaps suitable for soft-X-ray, ultraviolet (UV), infrared (IR), and visible color-generating element applications in video display devices used in items such as televisions and computer monitors.

In a specific embodiment of the invention, dopants are implanted into the nanorods to produce emitter devices. The nanorods can be easily doped with dopants, also referred to as impurity atoms, to become an n-type semiconductor that is suitable for use as a field emitter (cold cathode) and long-wavelength photo-emitter (photo-cathode); the nanorods can also be doped to become a p-type semiconductor such as a photo-emitter.

Because capillary condensation, instead of an extrinsic metallic catalyst, serves as the catalyst for nanorod growth, the resulting nanorods are aligned with the supporting matrix. Therefore, the matrix absorbs the lattice and thermal strain effects resulting in nanorods that are free from structural defects. The ion beam implantation step allows for control of nanorod density and patterning which results in predictable electric fields which promotes emission efficiency in field emission devices. The thin film growth step allows for control over the length-to-diameter aspect ratio. Consequently, nanorods with higher aspect ratios can be grown, which enhances the electron emission efficiency in electron emitting devices such as cold-cathodes, photo-cathodes, and field emitters.

We claim:

1. A method of making straightly aligned single crystal nanorods in designed patterned arrays comprising:
a) providing a substrate;
b) defining a pattern on the substrate;
c) implanting ions into the substrate using ion beam implantation; and
d) depositing thin films on the substrate.

2. The method of claim 1, wherein the step of providing a substrate comprises providing a substrate that is a semiconductor material.

3. The method of claim 1, wherein the step of providing a substrate comprises providing a substrate that is at lease one group compound selected from the group consisting of compounds derived from B, Al, Ga, In, Ti, Uut, N, P, As, Sb, Bi, Uup, and alloys thereof.

4. The method of claim 1, wherein the step of providing a substrate comprises providing a substrate that is at least one group II-VI compound selected from the group consisting of compounds derived from Zn, Cd, Hg, Uub, O, S, Se, Te, Pu, Uuh, and alloys thereof.

5. The method of claim 1, wherein the substrate comprises at least one group IV element.

6. The method of claim 1, wherein the substrate is Si.

7. The method of claim 1, wherein the substrate is Ge.

8. The method of claim 1, wherein the step of defining a pattern on the substrate comprises using lithography.

9. The method of claim 1, wherein the step of defining a pattern on the substrate comprises using photolithography.

10. The method of claim 1, wherein the step of implanting ions into the substrate comprises providing at least one ion selected from the group of ions consisting of Si, N, SiN, Ga, GaN, and combinations thereof.

11. The method of claim 1, wherein the step of implanting ions into the substrate comprises providing at least one ion selected from a group of ions consisting of Ga, N, GaN, XN, GaY, XY, XZ, YZ, and XYZ, and combinations thereof, wherein:
X is the first element of the substrate;
Y is the second element of the substrate; and
Z is the third element of the substrate.

12. The method of claim 1, wherein the step of implanting ions into the substrate comprises providing at least one ion selected from a group of ions consisting of Zn, O, ZnO, ZnY, XO, XY, XZ, YZ, XYZ, and combinations thereof, wherein:
X is the first element of the substrate;
Y is the second element of the substrate; and
Z is the third element of the substrate.

13. The method of claim 1, wherein the step of implanting ions into the substrate comprises providing at least one ion selected from a group of ions consisting of Ga, As, GaAs, GaY, XAs, XY, XZ, YZ, XYZ, and combinations thereof, wherein:
X is the first element of the substrate;
Y is the second element of the substrate; and
Z is the third element of the substrate.

14. The method of claim 1, wherein the step of implanting ions into the substrate comprises providing at least one ion selected from a group of ions consisting of Si, Ge, SiGe, SiY, XGe, XY, XZ, YZ, XYZ, and combinations thereof, wherein:
X is the first element of the substrate;
Y is the second element of the substrate; and
Z is the third element of the substrate.

15. The method of claim 1, wherein the step of implanting ions into the substrate comprises providing at least one ion selected from a group of ions consisting of In, N, InN, InY, XN, XY, XZ, YZ, XYZ, and combinations thereof, wherein:
X is the first element of the substrate;
Y is the second element of the substrate; and
Z is the third element of the substrate.

16. The method of claim 1, wherein the step of implanting ions into the substrate comprises providing at least one ion selected from a group of ions consisting of Ga, P, GaP, XP, GaY, XY, XZ, YZ, XYZ, and combinations thereof, wherein:
X is the first element of the substrate;
Y is the second element of the substrate; and
Z is the third element of the substrate.

17. The method of claim 1, wherein the step of implanting ions into the substrate comprises providing at least one ion selected from a group of ions consisting of Al, N, MN, XN, MY, XY, XZ, YZ, XYZ, and combinations thereof, wherein:
X is the fust element of the substrate;
Y is the second element of the substrate; and
Z is the third element of the substrate.

18. The method of claim 1, wherein the step of implanting ions into the substrate comprises providing at least one ion selected from a group of ions consisting of Al, N, In, AlN, InN, XN, AlY, InY, Al₁₋ₓInₓN, XY, XZ, YZ, XYZ, and combinations thereof, wherein:
X is the first element of the substrate;
Y is the second element of the substrate;
Z is the third element of the substrate; and
x is a value from zero to one.

19. The method of claim 1, wherein the step of implanting ions into the substrate comprises providing at least one ion selected from a group of ions consisting of Ga, N, In, GaN, InN, XN, GaY, InY, Ga₁₋ₓInₓN, XY, XZ, YZ, XYZ, and combinations thereof, wherein:
X is the first element of the substrate;
Y is the second element of the substrate;
Z is the third element of the substrate; and
x is a value from zero to one.

20. The method of claim 1, wherein the step of implanting ions into the substrate comprises providing at least one ion selected from a group of ions consisting of Ga, N, Al, GaN, MN, XN, GaY, MY, Ga₁₋ₓAlₓN, XY, XZ, YZ, XYZ, and combinations thereof, wherein:
X is the first element of the substrate;
Y is the second element of the substrate;
Z is the third element of the substrate; and
x is a value from zero to one.

21. The method of claim 1, wherein the step of implanting ions into the substrate comprises providing at least one ion selected from a group of ions consisting of X, Y, Z, and combinations thereof, wherein:
X is the first element of the substrate;
Y is the second element of the substrate; and
Z is the third element of the substrate.

22. The method of claim 1, wherein density and size of the nanorods in designed patterned arrays is controlled by dopant species, dosage, energy, and temperature used during the step of implanting ions into the substrate.

23. The method of claim 1, wherein a length-to-diameter aspect ratio of the nanorods in designed patterned arrays is controlled by time, temperature, and gas mixture ratio used during the step of depositing thin films on the substrate.

24. The method of claim 1, wherein the step of depositing thin films on the substrate comprises using molecular beam epitaxy.

25. The method of claim 1, wherein the step of depositing thin films on the substrate comprises using chemical vapor deposition.

26. The method of claim 1, wherein the step of depositing thin films on the substrate comprises using physical vapor deposition.

27. The method of claim 1, wherein the step of depositing thin films on the substrate comprises using pulsed laser deposition.

28. The method of claim 1, wherein the step of depositing thin films on the substrate comprises using sputtering.

29. The method of claim 1, wherein the step of depositing thin films on the substrate comprises depositing at least one thin film selected from a group consisting of GaN, ZnO, GaAs, SiGe, InN, and combinations thereof.

30. The method of claim 1, wherein the step of depositing thin films on the substrate comprises depositing at least one thin film selected from a group consisting of GaN, ZnO, GaAs, SiGe, InN, GaP, MN, Al₁₋ₓInₓN, Ga₁₋ₓInₓN, and Ga₁₋ₓAlₓN, and combinations thereof, wherein x is a value from zero to one.

31. The method of claim 1, wherein the straightly aligned single crystal nanorods in designed patterned arrays are aligned relative to a surface of the substrate.

32. Straightly aligned single crystal nanorods in designed patterned arrays produced according to the process of claim 1.

33. An emitter device prepared by a process comprising doping the straightly aligned single crystal nanorods produced according to the process of claim 1 with dopants.

34. The method of claim 33, wherein the step of doping the straightly aligned single crystal nanorods comprises using ion beam implantation.

35. The method of claim 33, wherein the step of doping the straightly aligned single crystal nanorods comprises using diffusion.

36. A method of making a straightly aligned single crystal GaN nanorods in designed patterned arrays comprising:
a) providing a Si substrate;
b) defining a pattern on the substrate using lithography;
c) implanting ions into the substrate using ion beam implantation, wherein the step of implanting ions into the substrate comprises providing at least one ion selected from the group consisting of Si, N, SiN, Ga, GaN, and combinations thereof; and
d) depositing GaN thin films on the substrate via molecular beam epitaxy growth, wherein nanotrenches form to catalyze the growth of GaN nanorods through capillary condensation of Ga atoms.

37. A method of making a straightly aligned single crystal GaN nanorods in designed patterned arrays comprising:
a) providing a Si substrate;
b) defining a pattern on the substrate using photolithography;
c) implanting Si ions into the substrate using ion beam implantation, wherein density and size of nanorods in the array pattern is controlled by the dosage, energy, and temperature; and
d) depositing GaN thin films on the substrate via nitrogen plasma enhanced molecular beam epitaxy growth, wherein nanotrenches form to catalyze the growth of GaN nanorods through capillary condensation of Ga atoms, wherein the GaN nanorod arrays are aligned relative to a surface of the substrate; wherein a length-to-diameter aspect ratio of the nanorods is controlled by time, temperature, and Ga/N ratio.
